(19) United States
(12) Patent Application Publication
(10) Pub. No.: US 2026/0334308 A1
(43) Pub. Date: Oct. 22, 2026

(54) STACKED SEMICONDCUTOR PACKAGE

(71) Applicant: TEXAS INSTRUMENTS INCORPORATED, DALLAS, TX (US)

(72) Inventors: Sachin Ishwar Gojagoji, Bangalore (IN); Shambhavi Awasthi, BILASPUR (IN); Hegde Ashish Hegde, Banagalore (IN)

(21) Appl. No.: 19/314,582

(22) Filed: Aug. 29, 2025

(30) Foreign Application Priority Data
Sep. 11, 2024 (IN) 202441068877

(51) Int. Cl. H01L 23/00; H01L 25/065; H10D 80/30

(52) U.S. Cl. CPC H10W 90/00; H10D 80/30; H10W 72/00; H10W 72/073; H10W 72/07336; H10W 72/07554; H10W 72/387; H10W 90/28; H10W 90/736; H10W 90/752; H10W 90/754; H10W 90/756

(57) ABSTRACT

A semiconductor package includes a first semiconductor die having a clip region and a non-clip region on a surface of the first semiconductor die. The non-clip region includes bond pads. The semiconductor package includes a second semiconductor die positioned over the first semiconductor die. The semiconductor package includes a clip covering the clip region of the first semiconductor die and being positioned between the first semiconductor die and the second semiconductor die. The clip is electrically connected to the clip region of the first semiconductor die via solder. The semiconductor package includes a polyimide barrier disposed on the non-clip region of the first semiconductor die between the clip and the bond pads.

### CROSS-REFERENCE TO RELATED APPLICATION

This application claims the benefit of priority to Indian Provisional Application No. 202441068877, filed on 11 Sep. 2024 the entirety of which is herein incorporated by reference.

### TECHNICAL FIELD

The present disclosure relates to stacked semiconductor packages with multiple semiconductor dies.

### BACKGROUND

Semiconductor packaging technology has evolved to address the increasing demands for higher power density and improved electrical performance in electronic systems. MCM (Multi-chip module) packages represent an approach for integrating multiple semiconductor dies within a single package to achieve enhanced functionality and performance characteristics. These packages employ wire bonding techniques to establish electrical connections between different semiconductor dies and external leads, enabling complex circuit implementations in compact form factors.

Stacked semiconductor architectures have emerged as a solution for achieving uniform current distribution and inter-die bonding capabilities in power applications. The semiconductor dies in such configurations sometimes use conductive clips that are positioned between stacked dies to facilitate electrical connections. The assembly process for these stacked configurations involves depositing solder on designated regions of the semiconductor dies, followed by positioning the conductive clips and establishing the needed electrical connections through wire bonding to external leads. These packaging methods have been employed across various applications requiring high power delivery, including applications where reliable power distribution is needed.

### SUMMARY

A first example relates to a semiconductor package that includes a first semiconductor die having a clip region and a non-clip region on a surface of the first semiconductor die. The non-clip region includes bond pads. The semiconductor package includes a second semiconductor die positioned over the first semiconductor die. The semiconductor package includes a clip covering the clip region of the first semiconductor die and being positioned between the first semiconductor die and the second semiconductor die. The clip is electrically connected to the clip region of the first semiconductor die via solder. The semiconductor package includes a polyimide barrier disposed on the non-clip region of the first semiconductor die between the clip and the bond pads.

A second example relates to a method of fabricating a semiconductor package. The method includes forming a polyimide barrier on a non-clip region of a first semiconductor die. The first semiconductor die has a clip region and the non-clip region on a surface of the first semiconductor die. The non-clip region includes bond pads. The method also includes mounting a first semiconductor die on an interconnect and depositing solder on the clip region of the first semiconductor die. The method includes positioning a clip to cover the clip region of the first semiconductor die and positioning a second semiconductor die over the clip and the first semiconductor die with the clip positioned between the first semiconductor die and the second semiconductor die.

### BRIEF DESCRIPTION OF THE DRAWINGS

FIG. 1 illustrates a semiconductor package in a stacked configuration.

FIG. 2 illustrates an isometric view of a semiconductor package in a stacked configuration.

FIG. 3A illustrates an overhead view of a semiconductor die.

FIG. 3B illustrates an overhead view of the semiconductor die of FIG. 3A that includes a deposition of solder.

FIG. 4A shows a conventional configuration where PIOR (polyimide opening resist) covers nearly an entire semiconductor die.

FIG. 4B illustrates a layout configuration for a semiconductor die where PIOR is selectively applied.

FIGS. 5, 6A, 6B, 7 and 8 illustrate stages of method for forming a semiconductor package in a stacked configuration.

FIG. 9 illustrates a flowchart of an example method for forming a semiconductor package with a polyimide barrier.

### DETAILED DESCRIPTION

This description relates to semiconductor packaging technology for power applications, specifically addressing problems encountered in stacked clip MCM (Multi-chip module) wire bond packages. In conventional approaches for assembling stacked semiconductor packages with power devices and controllers, significant challenges arise during the soldering process that connects a copper clip to the semiconductor die. The conventional approach required spacing the clip region about 400 micrometers away from bond pads to prevent solder contamination, which resulted in approximately 15% loss of active area on the semiconductor die. This substantial loss of active area leads to higher drain-to-source resistance, R_{DSON}, and needs larger die sizes to meet the same performance specifications, thereby increasing manufacturing costs.

Inclusion of a polyimide barrier on a semiconductor die curtails solder flux overflow during the assembly process. In situations where solder is deposited on the clip region of a semiconductor die and a copper clip is positioned over the semiconductor die, and the polyimide barrier is not included, the solder can flow through and over canals formed by the absence of metal top layer and polyimide material. This overflow contaminates the bond pads located proximate to an edge of the semiconductor die, creating electrical shorts between the bond pads and the clip, and causing NSOP (non-stick on pad) issues that prevent proper electrical connections. These contamination problems significantly impact the reliability and yield of the semiconductor packages leading to increased cost, particularly in high-power applications where uniform current distribution and robust electrical connections are needed.

To curtail the solder overflow, the polyimide barrier is disposed between the clip region and bond pads. The polyimide barrier enables reduced spacing of about 18 to 20 micrometers between an active area of the semiconductor die (e.g., a portion of the die underling the metal top layer that includes the clip region and a portion of the non-clip region) and bond pads while maintaining assembly reliability, thereby increasing active area utilization of the semiconductor die and improving performance without adding manufacturing cost. This approach utilizes existing polyimide processing operations, requiring no additional fabrication operations and provides enhanced reliability for clip-based stacked semiconductor packages used in power applications and/or other applications.

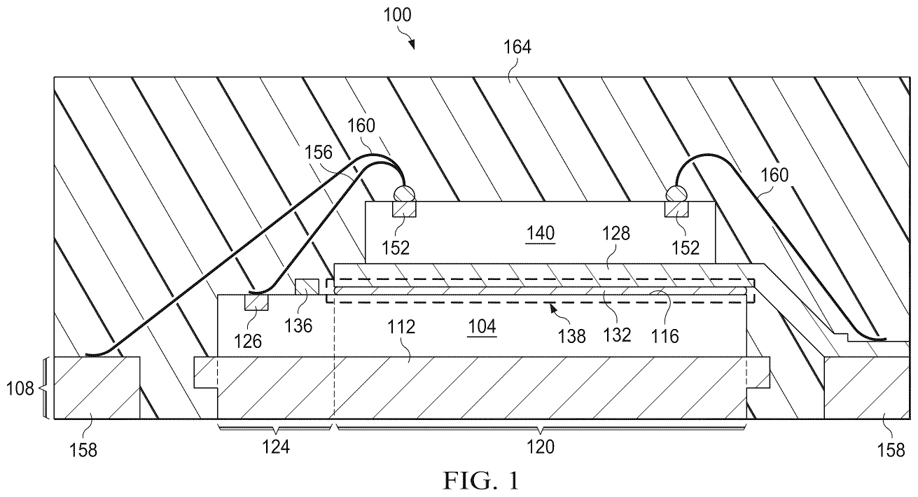

FIG. 1 illustrates a semiconductor package 100 in a stacked configuration. The semiconductor package 100 includes a first semiconductor die 104 mounted on an interconnect 108. More specifically, the first semiconductor die 104 is mounted on a die pad 112 of the interconnect 108. The semiconductor package 100 is a semiconductor device.

A first surface 116 of the first semiconductor die 104 includes a clip region 120 and a non-clip region 124 that are separate portions of the first surface 116. The non-clip region 124 includes bond pads 126 positioned proximate to an edge of the first semiconductor die 104. A clip 128 overlays the clip region 120 of the first semiconductor die 104 and is positioned between the first semiconductor die 104 and a second semiconductor die 140. The clip 128 is formed of a conductive material, such as copper (Cu) and provides uniform current distribution.

A layer of solder 132 electrically connects the clip 128 to the clip region 120 of the first semiconductor die 104. The clip region 120 includes a canal filled with the solder 132. The solder 132 extends across the clip region 120 and may flow into the non-clip region 124 during assembly.

A polyimide barrier 136 is disposed on the non-clip region 124 of the first semiconductor die 104 between the clip 128 and the bond pads 126. The polyimide barrier 136 has a rectangular wall-like shape and curtails (e.g., impedes and/or prevents) solder overflow from the clip region 120 of the first semiconductor die 104. The polyimide barrier 136 prevents the solder 132 from contaminating the bond pads 126, thereby avoiding shorts between the bond pads 126 and the clip 128 and/or other connections in the first semiconductor die 104. The first semiconductor die 104 also includes an active area 130 that underlies a metal top layer. The active area 138 includes the clip region 120 and a portion of the non-clip region 124. More particularly, the active area 130 includes the clip region 120 and a portion of the non-clip region 124 that is at least about 18 micrometers to about 20 micrometers away from the bond pads 126. Stated differently, an edge of the active area 130 is about 18 micrometers to about 20 micrometers away from the bond pads 126.

A second semiconductor die 140 is positioned over the first semiconductor die 104 with the clip 128 positioned between the first semiconductor die 104 and the second semiconductor die 140. The second semiconductor die 140 is affixed above the clip 128 with non-conductive die attach material (not shown) for electrical isolation from the first semiconductor die 104 and the clip 128. The second semiconductor die 140 includes bond pads 152. A first set of wire bonds 156 couples the bond pads 126 of the first semiconductor die 104 to the bond pads 152 of the second semiconductor die 140. A second set of wire bonds 160 couples the bond pads 152 of the second semiconductor die 140 to leads 158 of the interconnect 108. The clip 128 is also coupled to leads 158 of the interconnect 108. The semiconductor package 100 includes a mold compound 164 that encapsulates the first semiconductor die 104, the clip 128, the second semiconductor die 140 and a portion of the interconnect 108, such that portions of the die pad 112 and the leads 158 are exposed for external connections.

In some examples, the first semiconductor die 104 is a power circuit having a voltage rating up to about 80 volts and/or a current rating up to about 20 amperes. In such an example, the second semiconductor die 140 is a controller.

The semiconductor package 100 provides improved reliability and performance compared to conventional approaches that required spacing the clip region about 400 micrometers away from bond pads, which resulted in approximately 15% loss of active area. More particularly, the polyimide barrier 136 enables reduced spacing between the clip region 120 and the bond pads 126, increasing a size of the active area 138 while preventing solder overflow contamination. Moreover, fabrication of the semiconductor package 100 does not need additional fabrication operations because the polyimide barrier 136 utilizes an existing polyimide processing operation. Moreover, inclusion of the polyimide barrier 136 provides enhanced assembly reliability for clip-based stacked semiconductor packages and reduces resistance, particularly a reduced drain-to-source on resistance, R_{DSON} of FET (field effect transistors) implemented in the first semiconductor die 104. Moreover, including the polyimide barrier 136 improves yield during fabrication of the semiconductor package 100 with about 5% improvement in electrical performance while curtailing non-stick on pad failures.

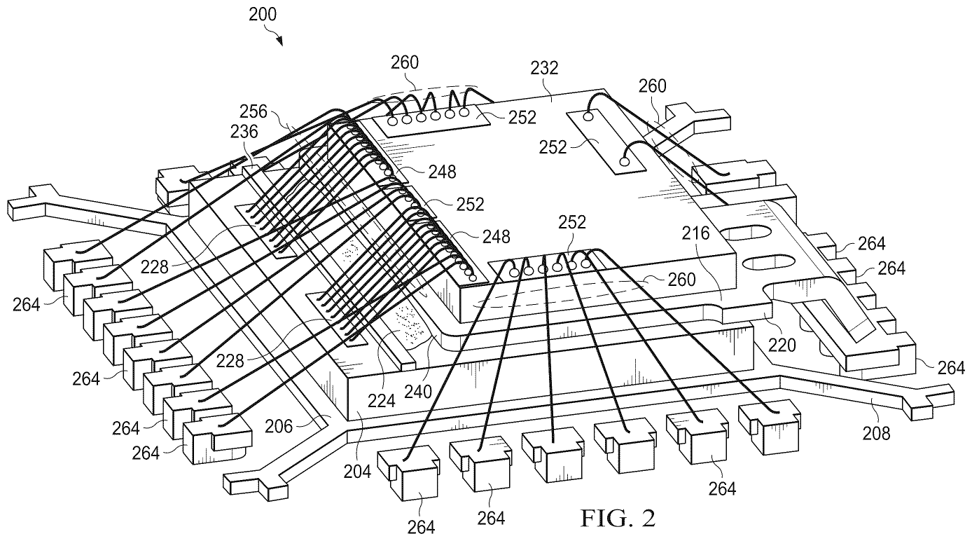

FIG. 2 illustrates an isometric view of a semiconductor package 200 in a stacked configuration that is employable to implement the semiconductor package 100 of FIG. 1. The semiconductor package 200 has a stacked architecture. The semiconductor package 200 includes the first semiconductor die 204 with a bottom surface (e.g., a first surface) mounted on a die pad 206 of an interconnect 208 (e.g., a leadframe). The first semiconductor die 204 has a top surface 216 (e.g., a second surface) that includes a clip region (covered by a clip 220) and a non-clip region 224. Bond pads 228 are positioned in the non-clip region 224 proximate to an edge of the first semiconductor die 204.

The clip 220 is positioned to overlay the clip region of the first semiconductor die 204. The clip 220 is formed of a conductive material such as copper (Cu) and facilitates uniform current distribution as well as reduced interconnect resistance of the first semiconductor die 204. The second semiconductor die 232 is mounted on the clip 220, such that the clip 220 is sandwiched between the first semiconductor die 204 and the second semiconductor die 232. The second semiconductor die 232 is affixed to the clip 220 with non-conductive die attach material (not shown) for electrical isolation from the first semiconductor die 204 and the clip 220. The clip 220 is electrically connected to the clip region of the first semiconductor die 204 via solder (not shown).

A polyimide barrier 236 is disposed on the non-clip region 224 of the first semiconductor die 204 between an edge 240 of the clip 220 and the bond pads 228. The polyimide barrier 236 curtails solder overflow from the clip region from contaminating the bond pads 228, thereby avoiding shorts between the bond pads 228 and the clip 220. In an example, the edge of an active area of the first semiconductor die 204 (a portion underlying a metal top layer) and the bond pads 228 of the first semiconductor die 204 are spaced apart by about 18 micrometers to about 20 micrometers.

The second semiconductor die 232 also includes a first set of bond pads 248 and a second set of bond pads 252. A first set of wire bonds 256 couple the bond pads 228 of the first semiconductor die 204 to the first set of bond pads 248 of the second semiconductor die 232. A second set of wire bonds 260 couple the second set of bond pads 252 of the second semiconductor die 232 to leads 264 (only some of which are labeled) of the interconnect 208. The clip 220 is also coupled to the leads 264 of the interconnect 208. A mold compound (not shown) encapsulates the first semiconductor die 204, the clip 220, the second semiconductor die 232 and a portion of the interconnect 208, such that connections for the die pad 206 and the leads 264 are exposed to enable connection to external components. In one example, the first semiconductor die 204 implements a power circuit and the second semiconductor die 232 implements a controller, such that the semiconductor package 200 is a power semiconductor package.

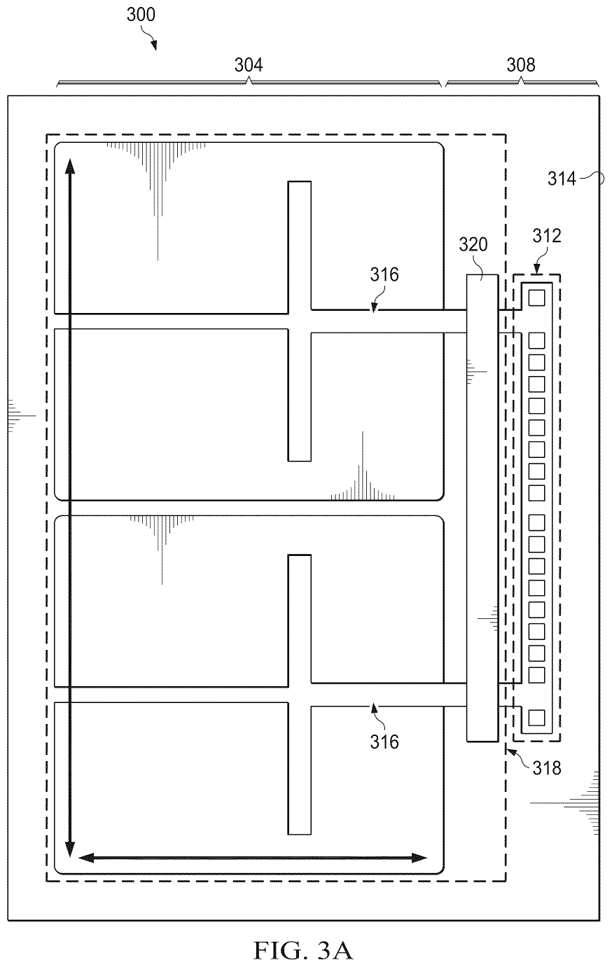

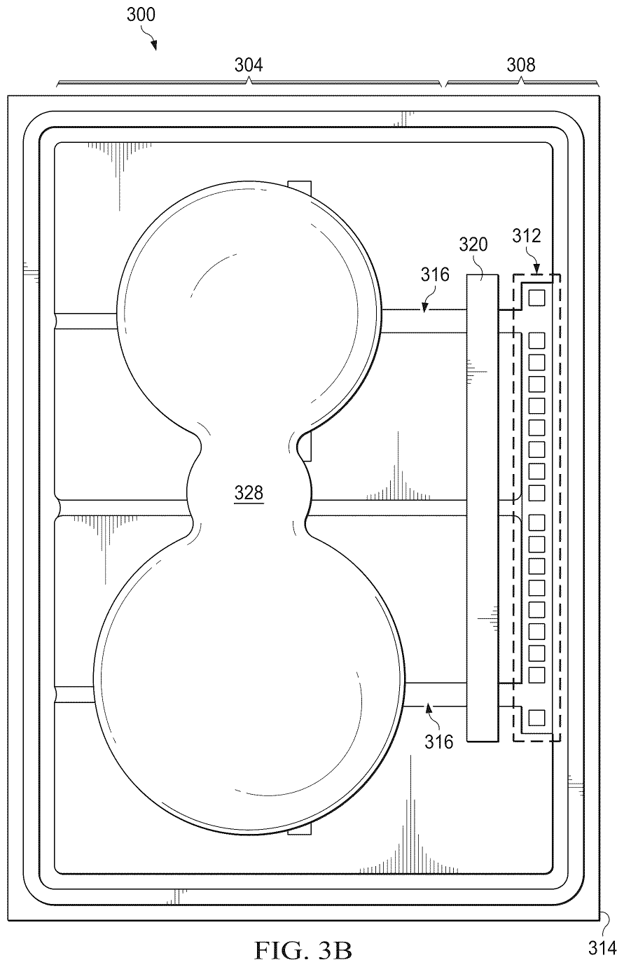

FIGS. 3A and 3B illustrate overhead views of the semiconductor die 300 for a stacked configuration that is employable to implement the first semiconductor die 104 of FIG. 1 and/or the first semiconductor die 204 of FIG. 2. The semiconductor die 300 includes a clip region 304 and a non-clip region 308 on a top surface of the semiconductor die 300. The non-clip region 308 includes bond pads 312 positioned proximate to an edge 314 of the semiconductor die 300. The clip region 304 is composed of canals 316 that are formed by an absence of a metal top layer (alternatively referred to as a METTOP layer), a PIOR (polyimide opening resist), enabling a trenching operation to form the canals that are about 10 micrometers deep. The depth of the canals is defined by the thickness (height) of the metal top layer, which is also about 10 micrometers deep in some examples. The semiconductor die 300 also includes an active area 318 that includes the clip region 304 and a portion of the non-clip region 308. The active area 318 is defined as a portion of the semiconductor die 300 underlying the metal top layer.

The semiconductor die 300 includes a polyimide barrier 320 disposed on the non-clip region 308 between the clip region 304 and the bond pads 312. The polyimide barrier 320 have a rectangular wall-like shape (e.g., a rectangular prism) and are positioned to impede solder overflow from the clip region 304. In some examples, an edge of the active area 318 and the bond pads 312 are spaced apart by about 18 micrometers to about 20 micrometers. The polyimide barrier 320 prevents solder from contaminating the bond pads 312, thereby avoiding shorts between the bond pads 312 and a clip that overlays the clip region 304.

FIG. 3B includes a deposition of solder 328 that flows into the canals 316. The polyimide barrier 320 curtails (e.g., impedes or eliminates) the flow of the solder 328, preventing the solder 328 from overflowing and contaminating the bond pads 312. In this manner, inclusion of the polyimide barrier 320 prevents an unintended short circuit between the bond pads 312 and the solder 328.

As illustrated by FIGS. 3A and 3B, the polyimide barrier 320 can be fabricated with an existing polyimide processing operation, requiring no additional fabrication operation. The polyimide barrier 320 enables reduced spacing between the clip region 304 and the bond pads 312 compared to conventional approaches that required spacing the clip region 304 about 400 micrometers away from bond pads, which resulted in approximately 15% loss of active area. The polyimide barrier 320 provides improved assembly reliability for clip-based stacked semiconductor packages and reduce resistance, particularly drain-to-source on resistance (R_{DSON}) of FETs (field effect transistors) implemented in the semiconductor die 300.

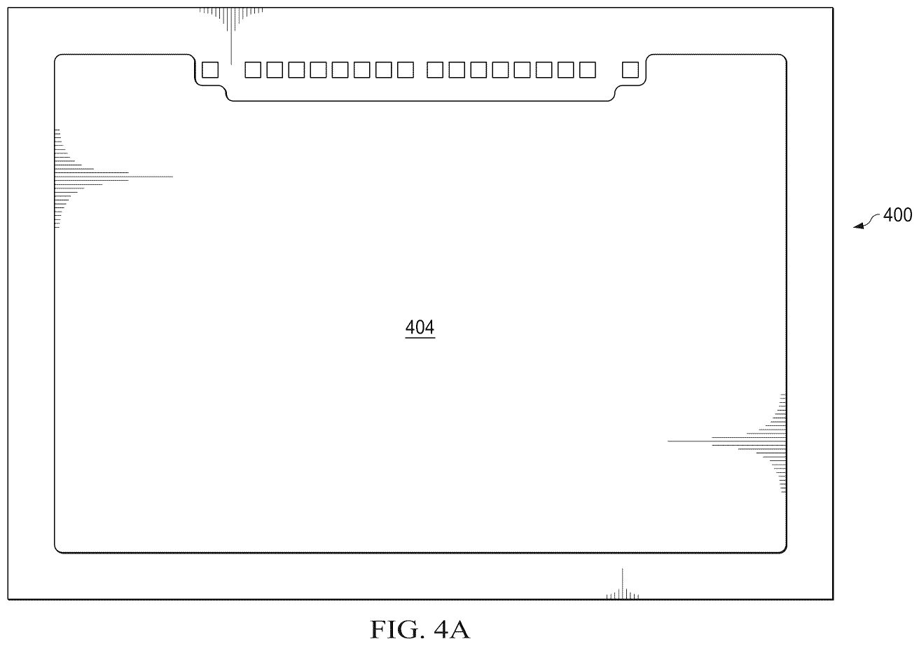

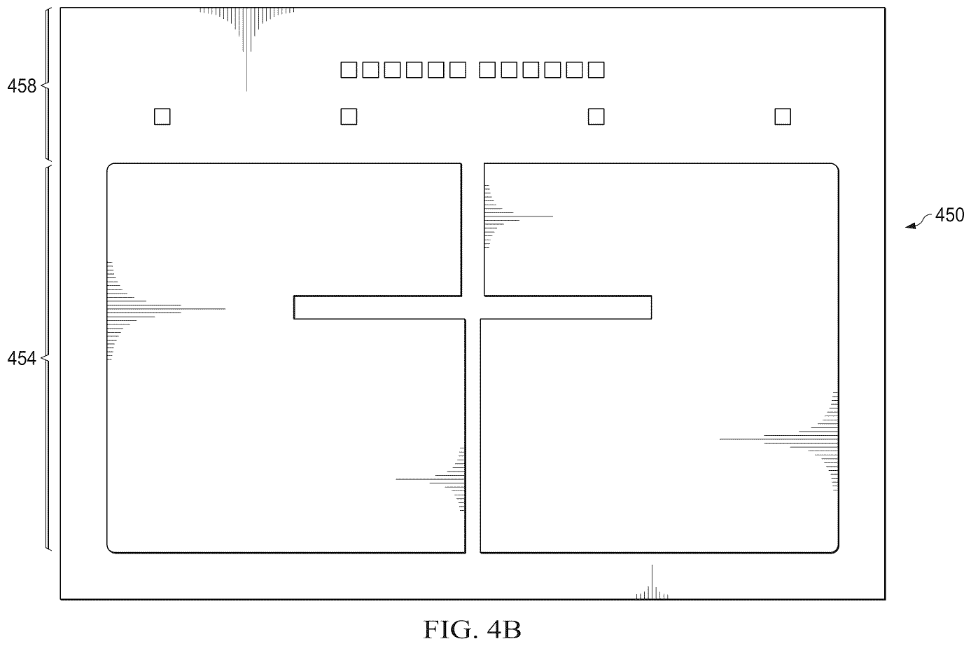

FIGS. 4A and 4B illustrate layout configurations for polyimide mask generation on a semiconductor die 400 and a semiconductor die 450, respectively. FIG. 4A shows a conventional configuration where PIOR (polyimide opening resist) covers nearly the entire semiconductor die 400, resulting in little polyimide generation on silicon. The shaded regions 404 in FIG. 4A represent regions where polyimide is drawn in the layout mask, which corresponds to regions where polyimide will not be present in the fabricated semiconductor die 400.

FIG. 4B illustrates a layout configuration for the semiconductor die 450 where PIOR is selectively applied. In this configuration, polyimide opening resist is generated only in specific regions 454, allowing polyimide material to be deposited in non-shaded regions 458 of the layout. The non-shaded regions in FIG. 4B indicate regions where polyimide will be deposited on the semiconductor die 450, creating the physical barrier between clip regions and bond pad regions.

The layout modification shown in FIG. 4B enables the formation of a polyimide barrier without requiring additional fabrication steps. By enabling polyimide coverage from specific regions in the layout design, namely the non-shaded regions 458, polyimide material is deposited in those regions during the existing polyimide processing operation. This approach enables the creation of a rectangular wall-like barrier (e.g., the polyimide barrier 136 of FIG. 1 and/or the polyimide barrier 236 of FIG. 2) that curtails solder overflow from contaminating bond pads while maintaining the reduced spacing of about 18 to 20 micrometers between an active area and bond pads.

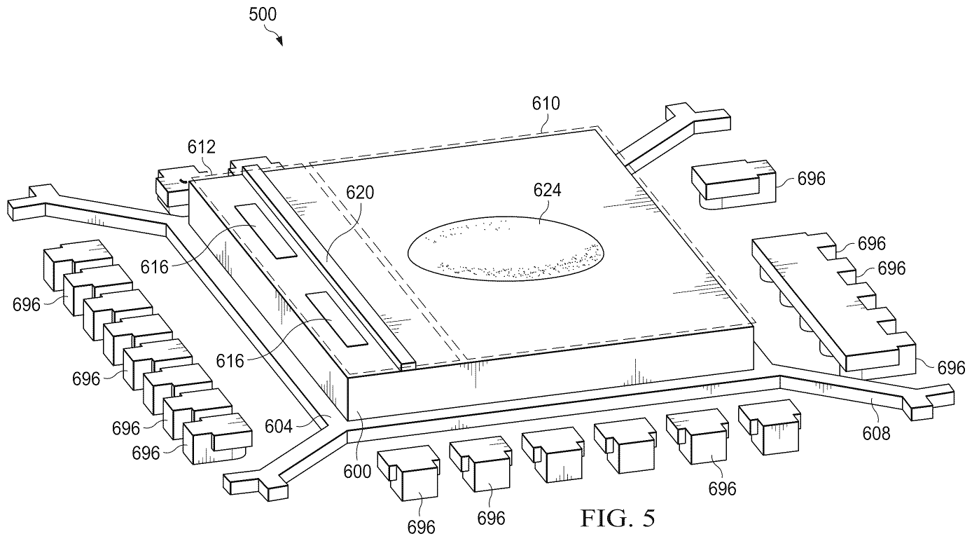

FIGS. 5, 6A, 6B, 7 and 8 illustrate a method for forming a semiconductor package in a stacked configuration, such as the semiconductor package 100 of FIG. 1 and/or the semiconductor package 200 of FIG. 2. For purposes of simplification, FIGS. 5, 6A, 6B, 7 and 8 employ the same reference numbers to denote the same structure.

As illustrated in FIG. 5, in a first stage 500 of the method, a first semiconductor die 600 is mounted on a die pad 604 of an interconnect 608 (e.g., a leadframe). The first semiconductor die 600 can be implemented with the first semiconductor die 104 of FIG. 1. The first semiconductor die 600 has a top surface that includes a clip region 610 and a non-clip region 612. The first semiconductor die 600 includes bond pads 616 that are positioned in the non-clip region 612 proximate to an edge of the first semiconductor die 600. A polyimide barrier 620 is disposed on the non-clip region 612 between the clip region 610 and the bond pads 616. Solder 624 is deposited on the clip region of the first semiconductor die 600.

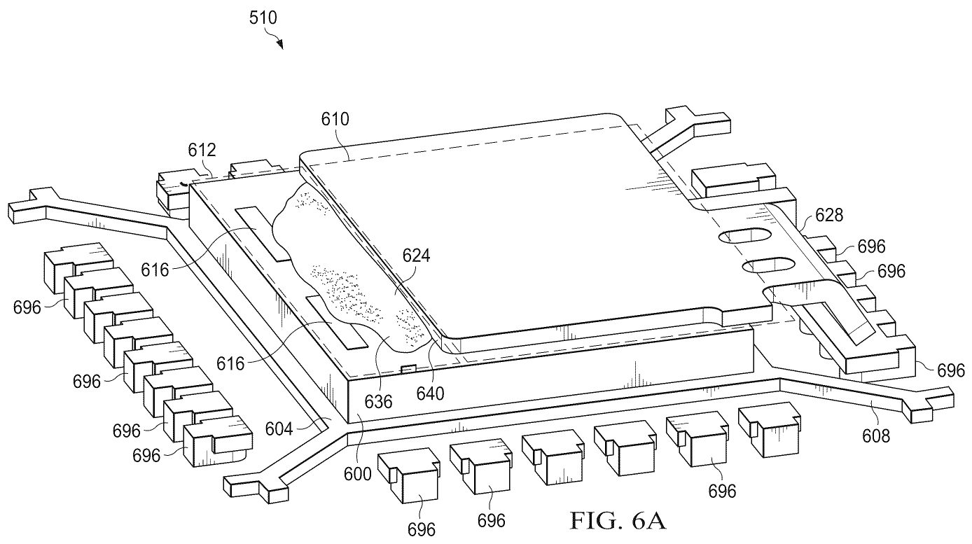

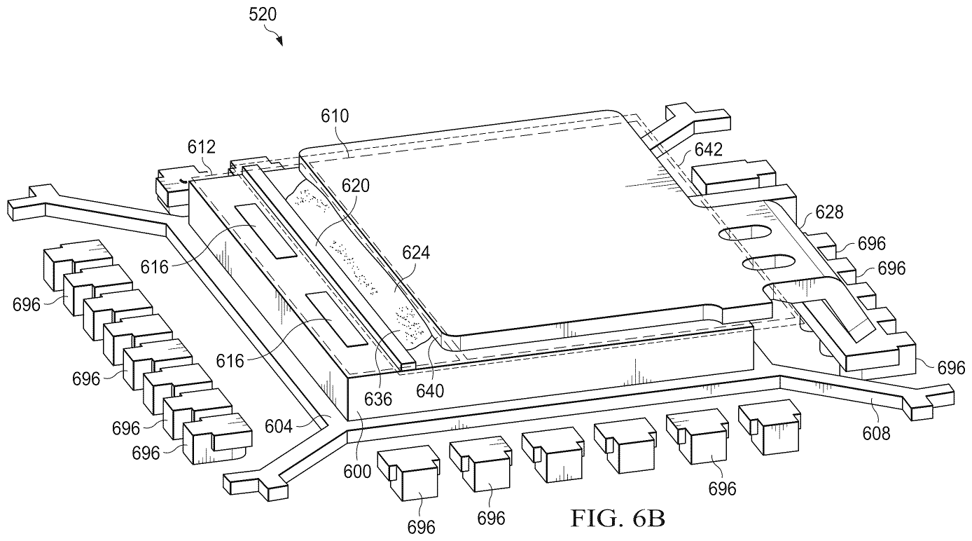

As illustrated in FIG. 6A, the polyimide barrier 620 is omitted for a conventional second stage 510. In the conventional second stage 510, a clip 628 is positioned over the clip region 610 of the first semiconductor die 600 where no polyimide barrier is present. In this conventional second stage 510, solder overflow 636 contaminates bond pads 616, creating shorts and/or NSOP (non-stick on pad issues). In other conventional approaches the clip 628 is spaced from the bond pads by at least about 400 micrometers to prevent contamination, resulting in approximately 15% loss of active area for the first semiconductor die 600.

As illustrated in FIG. 6B, in a second stage 520 (an improved approach) of the method with the polyimide barrier 620, the clip 628 is positioned over the clip region 610 of the first semiconductor die 600, causing the solder 624 to spread (e.g., due to pressure), but the polyimide barrier 620 curtails solder overflow from reaching the bond pads 616. This configuration enables reduced spacing of about 18 to 20 micrometers between the edge of an active area 642 and the bond pads 616 of the first semiconductor die 600 while preventing contamination.

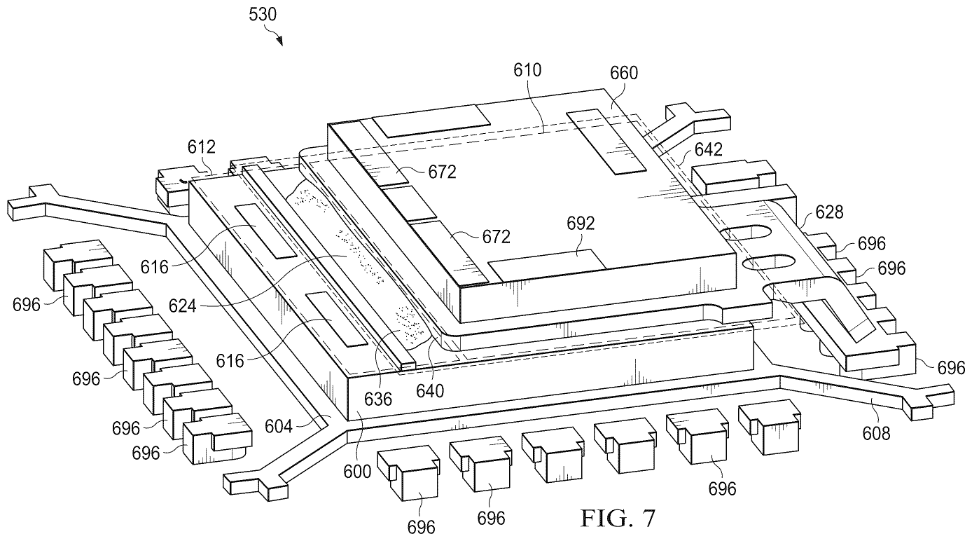

As illustrated in FIG. 7, in a third stage 530 of the method, a second semiconductor die 660 is positioned over the first semiconductor die 600 with the clip 628 sandwiched between the first semiconductor die 600 and the second semiconductor die 660. The second semiconductor die 660 includes bond pads 672 (only some of which are labeled). The polyimide barrier 620 continues to curtail solder overflow allowing the compact spacing between the active area 642 and the bond pads 616 of the first semiconductor die 600.

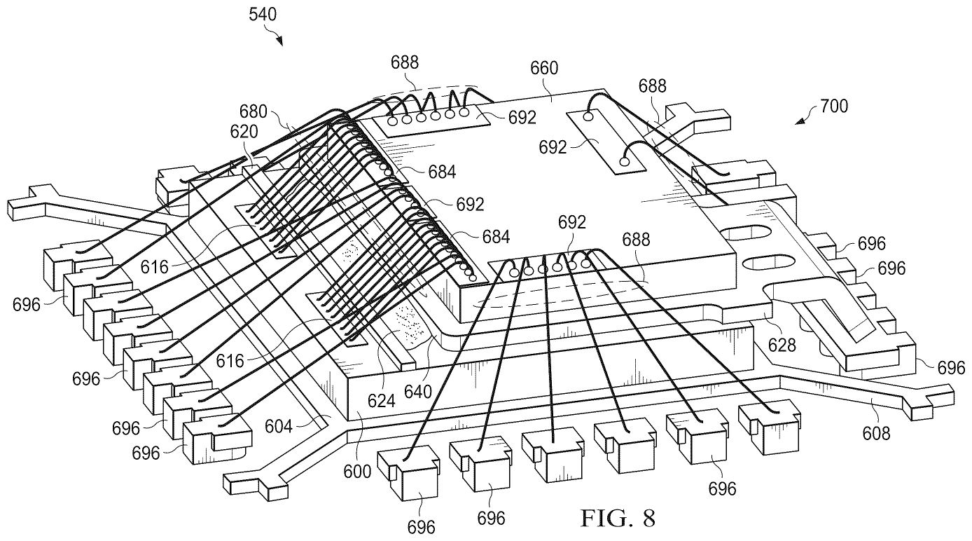

As illustrated in FIG. 8, in a fourth stage 540 of the method, wire bonding is applied to complete the semiconductor package. A first set of wire bonds 680 couples the bond pads 616 of the first semiconductor die 600 to a first set of bond pads 684 (a subset of the bond pads 672 of FIG. 7) of the second semiconductor die 660. A second set of wire bonds 688 couples a second set of bond pads 692 (a second subset of the bond pads 672 of FIG. 7) of the second semiconductor die 600 to leads 696 of the interconnect 608. The clip 628 is also coupled to the leads 696 of the interconnect 608. The entire assembly is subsequently encapsulated in a mold compound (not shown in this view) to form a semiconductor package 700 such that portions of the interconnect 608 (e.g., the die pad 604 and the leads 696) remain exposed for external connections.

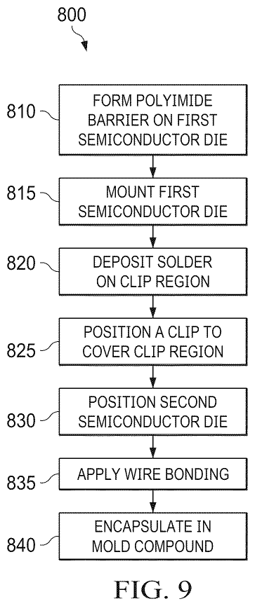

FIG. 9 illustrates a flowchart of an example method 800 for forming a semiconductor package with a polyimide barrier, such as the semiconductor package 100 of FIG. 1 and/or the semiconductor package 200 of FIG. 2.

At block 810, a polyimide barrier (e.g., the polyimide barrier 136 of FIG. 1) is formed on a first semiconductor die (e.g., the first semiconductor die 104 of FIG. 1). The polyimide barrier is disposed on a non-clip region (e.g., the non-clip region 124 of FIG. 1) of the first semiconductor die between a clip region (e.g., the clip region 120 of FIG. 1) and bond pads (e.g., the bond pads 126 of FIG. 1). At block 815, the first semiconductor die is mounted on an interconnect (e.g., the interconnect 108 of FIG. 1). At block 820, solder (e.g., the solder 132 of FIG. 1) is deposited on the clip region of the first semiconductor die.

At block 825, a clip (e.g., the clip 128 of FIG. 1) is positioned to cover the clip region of the first semiconductor die (e.g., the first semiconductor die 104 of FIG. 1). The clip is formed of a conductive material such as copper and provides uniform current distribution and to reduce interconnect resistance of the first semiconductor die. At block 830, a second semiconductor die (e.g., the second semiconductor die 140 of FIG. 1) is positioned over the first semiconductor die with the clip positioned between the first semiconductor die and the second semiconductor die.

At block 835, wire bonding (e.g., the first set of wire bonds 156 of FIG. 1 and the second set of wire bonds 160 of FIG. 1) is applied to couple bond pads of the first semiconductor die to bond pads (e.g., the bond pads 152 of FIG. 1) of the second semiconductor die and to couple bond pads of the second semiconductor die to leads (e.g., the leads 158 of FIG. 1) of the interconnect. At block 840, the first semiconductor die, the second semiconductor die and a portion of the interconnect are encapsulated in a mold compound (e.g., the mold compound 164 of FIG. 1) such that portions of the interconnect, namely the leads and the die pad, remain partially exposed for external connections.

In this description, unless otherwise stated, “about”, “approximately” or “nearly” preceding a parameter means being within +/−10 percent of that parameter. Further, in this description, the term “couple”, “coupled” or “couples” means either an indirect or direct connection. Modifications are possible in the described embodiments, and other embodiments are possible, within the scope of the claims.

What is claimed is:

1. A semiconductor package comprising:
a first semiconductor die having a clip region and a non-clip region on a surface of the first semiconductor die, the non-clip region having bond pads;
a second semiconductor die positioned over the first semiconductor die;
a clip covering the clip region of the first semiconductor die, and being positioned between the first semiconductor die and the second semiconductor die, the clip is electrically connected to the clip region of the first semiconductor die via solder; and
a polyimide barrier disposed on the non-clip region of the first semiconductor die between the clip and the bond pads.

2. The semiconductor package of claim 1, wherein the polyimide barrier impedes solder overflow from the clip region of the first semiconductor die.

3. The semiconductor package of claim 2, wherein the clip region of the first semiconductor die comprises a canal filled with the solder.

4. The semiconductor package of claim 1, wherein the non-clip region is proximate to an edge of the first semiconductor die.

5. The semiconductor package of claim 1, further comprising wire bonds coupled to the bond pads of the first semiconductor die and bond pads of the second semiconductor die.

6. The semiconductor package of claim 5, wherein the wire bonds are a first set of wire bonds, the semiconductor package further comprising an interconnect and a second set of wire bonds that couple the bond pads of the second semiconductor die to leads of the interconnect.

7. The semiconductor package of claim 6, wherein the clip is coupled to leads of the interconnect.

8. The semiconductor package of claim 1, wherein the first semiconductor die comprises a power circuit and the second semiconductor die comprises a controller.

9. The semiconductor package of claim 8, wherein the first semiconductor die has a voltage rating of about 80 volts.

10. The semiconductor package of claim 8, wherein the first semiconductor die has a current rating of about 20 amperes.

11. The semiconductor package of claim 1, wherein the clip comprises copper.

12. The semiconductor package of claim 1, wherein the clip is between the first semiconductor die and the second semiconductor die to provide uniform current distribution on the first semiconductor die.

13. The semiconductor package of claim 1, wherein an edge of an active area and the bond pads of the first semiconductor die are spaced apart by about 18 micrometers to about 20 micrometers.

14. A method of fabricating a semiconductor package comprising:
forming a polyimide barrier on a non-clip region of a first semiconductor die, the first semiconductor die having a clip region and the non-clip region on a surface of the first semiconductor die, the non-clip region including bond pads;
mounting a first semiconductor die on an interconnect;
depositing solder on the clip region of the first semiconductor die;
positioning a clip to cover the clip region of the first semiconductor die; and
positioning a second semiconductor die over the clip and the first semiconductor die with the clip positioned between the first semiconductor die and the second semiconductor die.

15. The method of claim 14, wherein the polyimide barrier impedes solder overflow from the clip region of the first semiconductor die.

16. The method of claim 14, wherein the clip region of the first semiconductor die comprises a canal filled with the solder.

17. The method of claim 14, wherein the non-clip region is proximate to an edge of the first semiconductor die.

18. The method of claim 14, further comprising coupling wire bonds to the bond pads of the first semiconductor die and the bond pads of the second semiconductor die.

19. The method of claim 14, wherein the first semiconductor die comprises a power circuit and the second semiconductor die comprises a controller.

20. The method of claim 14, wherein the second semiconductor die is affixed to the clip with non-conductive die attach material to electrically isolate the second semiconductor die from the clip and the first semiconductor die.
